(19) United States
(12) Patent Application Publication
(10) Pub. No.: US 2025/0239509 A1
(43) Pub. Date: Jul. 24, 2025

(54) SEMICONDUCTOR ASSEMBLY FOR PROVIDING AN ENHANCED MEMORY BANDWIDTH AND METHODS FOR FORMING THE SAME

(71) Applicant: Taiwan Semiconductor Manufacturing Company Limited, Hsinchu (TW)

(72) Inventors: Han-Jong Chia, Hsinchu City (TW); Chieh-Yen Chen, Taipei City (TW); Ke-Han Shen, Chiayi City (TW); Hung-Yi Kuo, Taipei City (TW)

(21) Appl. No.: 18/643,209

(22) Filed: Apr. 23, 2024

Related U.S. Application Data
(60) Provisional application No. 63/623,496, filed on Jan. 22, 2024.

(51) Int. Cl. H01L 23/498; H01L 21/48; H01L 23/00; H01L 25/065; H10B 80/00

(52) U.S. Cl. CPC H01L 23/49822; H01L 21/486; H01L 23/49838; H01L 24/05; H01L 24/13; H01L 24/97; H01L 25/0652; H01L 2224/05008; H01L 2224/05025; H01L 2224/13009; H01L 2224/13026; H01L 2224/97; H01L 2924/01029; H01L 2924/1433; H01L 2924/1436; H01L 2924/182; H10B 80/00

(57) ABSTRACT

A plurality of processor dies may be attached to an interposer structure including interposer dielectric material layers having formed therein interposer metal interconnect structures, A dielectric matrix may be formed around the plurality of processor dies over the interposer structure. A router die may be attached to the plurality of processor dies. The router die includes router dielectric material layers having formed therein router metal interconnect structures and a router substrate having formed therein router through-substrate via structures therein. A backside of the router substrate may be thinned to expose end surfaces of the router through-substrate via structures. Memory dies may be attached to the router substrate after thinning the backside of the router substrate. Bonding pads of the memory dies are electrically connected to the router through-substrate via structures.

### RELATED APPLICATIONS

This application claims priority from U.S. Provisional Application Ser. No. 63/623,426 titled “High Performance Memory—ASIC Array Integration” and filed on Jan. 22, 2024, the entire contents of which are incorporated herein by reference for all purposes.

### BACKGROUND

Traditional integration schemes for application-specific integrated circuit (ASIC) dies and memory dies encounter challenges in delivering adequate memory bandwidth as the performance levels of both ASIC and memory dies continue to rise. System performance and efficiency may be severely constrained by the inadequate memory bandwidth and relatively slow data transfer speeds. Consequently, limitations in memory bandwidth hinder advancements in high-performance computing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an exemplary structure including an interposer structure after formation of interposer metal interconnect structures and front interposer bonding pads formed within interposer dielectric material layers according to an embodiment of the present disclosure.

FIG. 2 is a vertical cross-sectional view of the exemplary structure after bonding processor dies to the interposer structure according to an embodiment of the present disclosure.

FIG. 3 is a vertical cross-sectional view of the exemplary structure after formation of a dielectric matrix according to an embodiment of the present disclosure.

FIG. 4 is a vertical cross-sectional view of a router die according to an embodiment of the present disclosure.

FIG. 5 is a vertical cross-sectional view of the exemplary structure after bonding the router die to an array of processor dies according to an embodiment of the present disclosure.

FIG. 6 is a vertical cross-sectional view of the exemplary structure after thinning a backside of the router die according to an embodiment of the present disclosure.

FIG. 7 is a vertical cross-sectional view of the exemplary structure after formation of a backside router dielectric layer and formation of backside router bonding pads according to an embodiment of the present disclosure.

FIG. 8 is a vertical cross-sectional view of the exemplary structure after attaching memory dies to the router die according to an embodiment of the present disclosure.

FIG. 9 is a vertical cross-sectional view of the exemplary structure after removal of a carrier substrate from the interposer structure according to an embodiment of the present disclosure.

FIG. 10 is a vertical cross-sectional view of the exemplary structure after formation of backside interposer bonding pads according to an embodiment of the present disclosure.

FIG. 11 is a top-down view of a semiconductor assembly formed by dicing of the exemplary structure of FIG. 10.

FIG. 12 is a circuit schematic that illustrates operation of the semiconductor assembly illustrated in FIGS. 10 and 11.

FIG. 13 schematically illustrates a change in the operating regime of a computing device comprising the semiconductor assembly of the present disclosure relative to previously known computing devices.

FIG. 14 is a flowchart illustrating general processing steps for forming a semiconductor assembly of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Elements with the same reference numerals are presumed to be the same element or similar elements, and are presumed to have the same material composition and provide the same function, unless expressly described otherwise.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise. As used herein, an element or a system “configured for” a function or an operation or “configured to” provide or perform a function or an operation refers to an element or a system that is provided with hardware, and with software as applicable, to provide such a function or such an operation as described in the present disclosure, and as known in the art in the event any details of such hardware or such software are not expressly described herein.

The present disclosure is directed generally to semiconductor devices, and particularly to a semiconductor assembly that includes application-specific integrated circuit (ASIC) dies and memory dies (such as high-bandwidth memory (HBM) dies) configured to enhance memory bandwidth. The integration of ASIC dies and memory dies is facilitated through a network-on-chip (NoC) architecture, utilizing chip-on-wafer-on-substrate (CoWoS) technology and through-silicon vias (TSVs) for enhanced connectivity and performance. The integration scheme of the present disclosure uses a modular design framework that boosts scalability and adaptability, optimizes data transfer and processing with its direct high-speed data paths, and provides efficient thermal management.

The network-on-chip architecture used in various embodiments disclosed herein integrates ASIC dies with memory dies through high-speed, low-latency data paths provided within a network-on-chip router. The physical distance between the ASIC dies and the memory dies may be reduced through the use of a network-on-chip router, which provides high operational efficiency and robust thermal tolerance. The network-on-chip router uses through-silicon via (TSV) structures to provide electrical connections to memory dies. The use of the TSV structures may increase memory capacity and bandwidth and allows for the integration of a large number of memory dies. Data flow through the network-on-chip router may be dynamically managed to optimize resource utilization. The network-on-chip architecture may be embodied in a semiconductor assembly formed by chip-on-wafer-on-substrate (CoWoS) technology and hybrid bonding, reducing memory latency and increasing memory efficiency.

Memory capacity and the bandwidth of a computing system may be increased through the network-on-chip architecture of the present disclosure. Further, embodiments of the present disclosure provide performance boosts, enhanced efficiency, and reduced power consumption for environmental sustainability, superior thermal management for reliability, and design scalability for future advancements.

The present disclosure provides a scalable, high-performance solution for enhancing the performance of high-end computing systems.

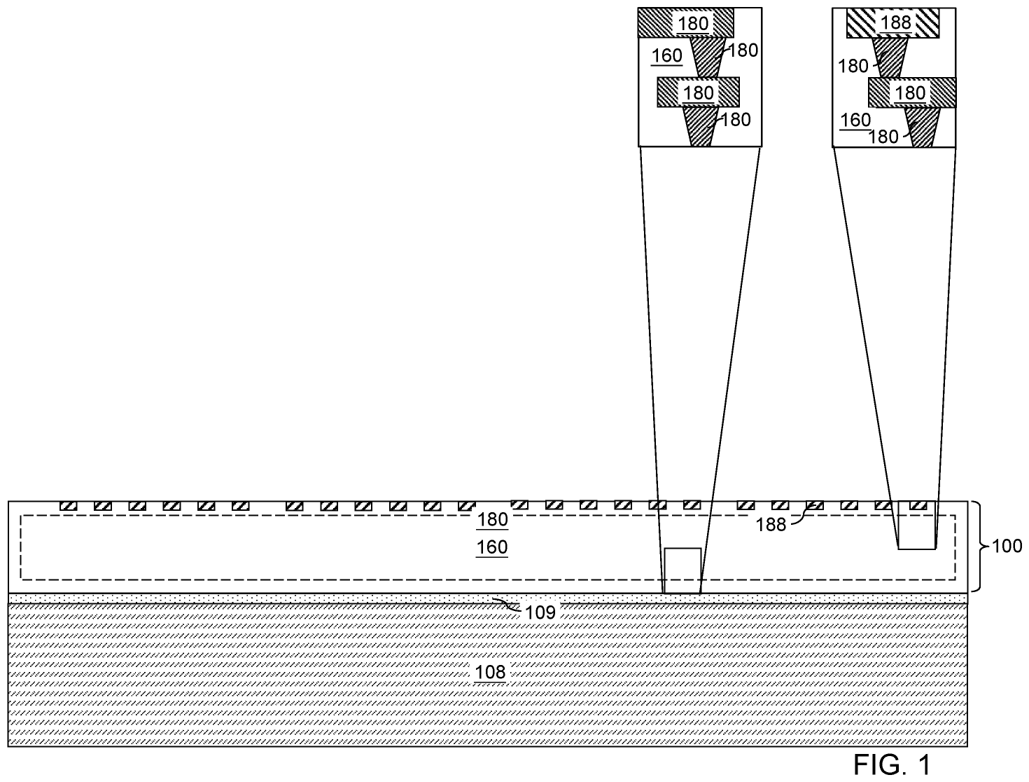

Referring to FIG. 1, an exemplary structure including an interposer structure 100 formed on a carrier substrate 108 is illustrated. The carrier substrate 108 may be a commercially available silicon wafer. An interfacial material layer 109 may be formed on a top surface of the carrier substrate 108. The interfacial material layer 109 may comprise a thermally-decomposable adhesive material, or any other material that may be used as a stopper material during subsequent removal of the carrier substrate 108.

The interposer structure 100 may be formed by depositing interposer dielectric material layers 160 over the carrier substrate 108. Interposer metal interconnect structures 180 and front interposer bonding pads 188 may be formed within the interposer dielectric material layers 160. The interposer dielectric material layers 160 may comprise interlayer dielectric (ILD) materials as known in the art, which may comprise, for example, undoped silicate glass, a doped silicate glass, silicon nitride, silicon carbide nitride, dielectric metal oxides, etc. In one embodiment, the interposer dielectric material layers 160 may comprise, and/or may consist essentially of, inorganic dielectric materials. The interposer metal interconnect structures 180 may comprise metal via structures and metal line structures. In some embodiments, sidewalls of the metal via structures may be tapered such that a lateral dimension (such as a diameter) of each metal via structure increases with a vertical distance from a top surface of the carrier substrate 108. The total number of levels of the metal line structures may be in a range from 1 to 12, although a greater number of levels may also be used. The interposer metal interconnect structures 180 may comprise copper, aluminum, tungsten, titanium, or other metals providing high electrical conductivity. The interposer metal interconnect structures 180 may be configured to provide electrical connections to and from a plurality of processor dies to be subsequently bonded thereupon.

The front interposer bonding pads 188 may be formed at the topmost level of the interposer dielectric material layers 160. The topmost dielectric material layer selected from the interposer dielectric material layers 160 is also referred to as interposer bonding dielectric layer. The interposer bonding dielectric layer may comprise a dielectric material that may be used for dielectric-to-dielectric bonding such as silicon oxide-to-silicon oxide bonding. In one embodiment, the interposer bonding dielectric layer may comprise undoped silicate glass or a doped silicate glass.

The front interposer bonding pads 188 may be configured for metal-to-metal bonding such as copper-to-copper bonding. As used herein, a “metal-to-metal” bonding refers to a bonding in which two metal surfaces are directly bonded to each other without any intervening material portion such as a solder material portion. Thus, atomic interdiffusion of metal atoms occurs across a bonding interface, and grain growth and recrystallization of metallic materials occur during a metal-to-metal bonding. In one embodiment, the front interposer bonding pads 188 may comprise copper bonding pads having copper surfaces as bonding surfaces.

The front interposer bonding pads 188 may be arranged as multiple arrays each having a respective pitch along repetition directions. Generally, the pattern of each array of front interposer bonding pads 188 may be a mirror image pattern of the pattern of front processor bonding pads of processor dies to be subsequently bonded to the interposer structure 100. According to an aspect of the present disclosure, the front interposer bonding pads 188 may be configured in a pattern for bonding with multiple processor dies, such as a two-dimensional array of processor dies.

The region illustrated in FIG. 1 corresponds to the area of a single interposer structure 100. Generally, a two-dimensional array of interposer structures 100 may be formed on a carrier substrate 108. It is understood that the illustrated portion of the exemplary structure may be repeated in a two-dimensional array such that a plurality of interposer structures 100 are provided over the carrier substrate 108. The area of each interposer structure 100 may corresponds to the area of a single reticle (which may be about 30 mm×30 mm), or may extend over areas of multiple reticles. The area of each interposer structure 100 may be selected based on the total number of memory dies to be subsequently attached to an assembly including the interposer structure 100.

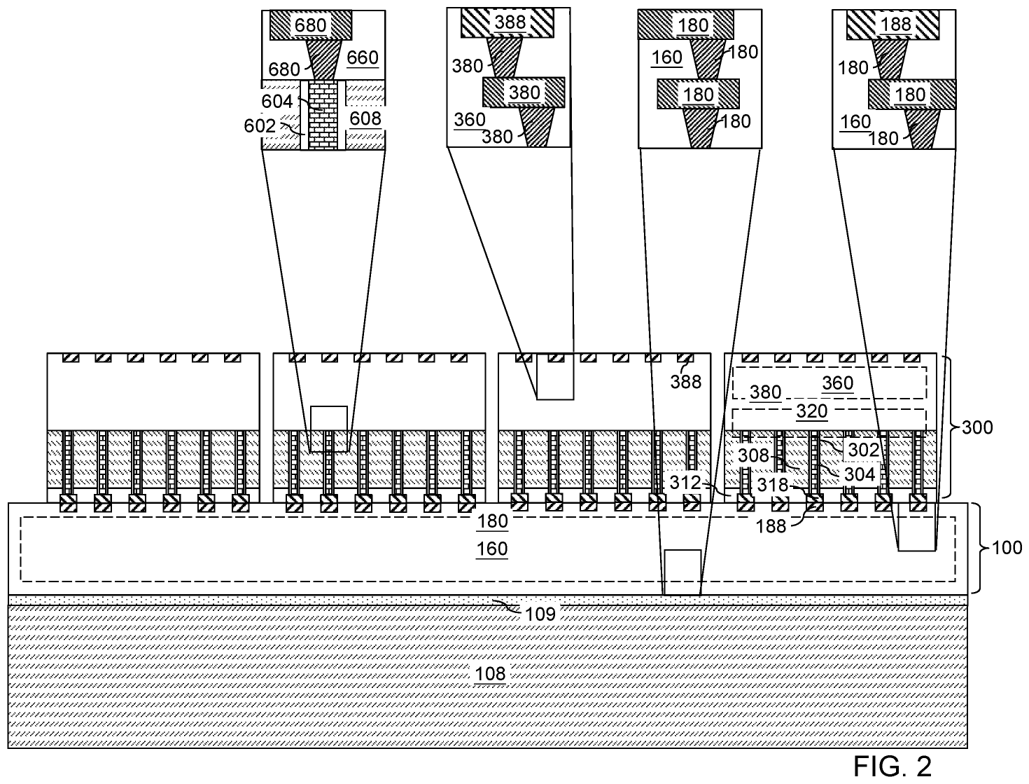

Referring to FIG. 2, a plurality of processor dies 300 may be attached to the interposer structure 100. In one embodiment, the plurality of processor dies 300 may be attached to the interposer structure 100 via metal-to-metal bonding and dielectric-to-dielectric bonding. Alternatively, at least one of the plurality of processor dies 300 may be attached to the interposer structure 100 via microbump bonding (also known as C2 bonding or chip connection bonding), C4 (controlled collapse chip connection) bonding, or alternative chip attachment methods. Each processor die 300 comprises a processor-die substrate 308, which may be a semiconductor substrate such as a single crystalline silicon substrate. Each processor die 300 comprises through-substrate via structures 304 vertically extending through the processor-die substrate 308. The through-substrate via (TSV) structures 304 are electrically isolated from the processor-die substrate 308 by insulating spacers 302, which are also referred to as processor-die insulating spacers. The insulating spacers 302 may have a tubular configuration.

Each processor die 300 includes at least one processing unit 320 therein. A processing unit 320 may be any of a central processing unit (CPU), a graphics processing unit (GPU), digital signal processor (DSP), a neural processing unit (NPU), an artificial intelligence (AI) accelerator, etc. Further, a processor die 300 may include multiple processing units as in the case of a system-on-chip (SoIC) die. For example, an SoIC die may comprise a CPU, a GPU, a DSP, and/or an NPU. In addition, a processor die 300 may optionally include a cache memory, which is referred to as an L1 cache memory (i.e., a first-level cache memory) which may comprise a static random access memory (SRAM). Such a cache memory that is present within a processor die 300 is generally referred to as an embedded cache memory. Additional cache memory, which is referred to as an L2 cache memory (i.e., a second-level cache memory) may be incorporated into one or more of the processor dies 300. Generally, the L2 cache memory may have a larger memory capacity and a slower access speed relative to the L1 cache memory.

Each processor die 300 includes a set of die dielectric material layers 360 having formed therein a set of die metal interconnect structures 380 and a set of front processor bonding pads 388. The die dielectric material layers 360 may comprise interlayer dielectric (ILD) materials as known in the art. In one embodiment, the die dielectric material layers 360 may comprise, and/or may consist essentially of, inorganic dielectric materials. The die metal interconnect structures 380 may comprise metal via structures and metal line structures. The total number of levels of the metal line structures may be in a range from 2 to 16, although a greater number of levels may also be used. The die metal interconnect structures 380 may comprise copper, aluminum, tungsten, titanium, or other metals providing high electrical conductivity.

The front processor bonding pads 388 may be formed at the topmost level of the die dielectric material layers 360. The topmost dielectric material layer selected from the die dielectric material layers 360 is also referred to as processor bonding dielectric layer, and may comprise a dielectric material that may be used for dielectric-to-dielectric bonding such as silicon oxide-to-silicon oxide bonding. In one embodiment, the processor bonding dielectric layer may comprise undoped silicate glass or a doped silicate glass. The front processor bonding pads 388 may be configured for metal-to-metal bonding such as copper-to-copper bonding. In one embodiment, the front processor bonding pads 388 may comprise copper bonding pads having copper surfaces as bonding surfaces.

Each processor dies 300 may comprise a backside die dielectric layer 312 located on the backside surface of the processor-die substrate 308. The backside die dielectric layer 312 may comprise a dielectric material that may be used for dielectric-to-dielectric bonding. For example, the backside die dielectric layer 312 may comprise undoped silicate glass or a doped silicate glass. Backside processor bonding pads 318 may be formed in the backside die dielectric layer 312 on backside end surfaces of the through-substrate via structure 304. The backside processor bonding pads 318 may be configured for metal-to-metal bonding such as copper-to-copper bonding. In one embodiment, the backside processor bonding pads 318 may comprise copper bonding pads having copper surfaces as bonding surfaces. The backside processor bonding pads 318 are located on the die through-substrate via structures 304.

The processor dies 300 may be attached to the interposer structure 100 by bonding the backside processor bonding pads 318 to front interposer bonding pads 188 of the interposer structure 100. Thus, the through-substrate via structures 304 are electrically connected to the front interposer bonding pads 188 upon attaching the plurality of processor dies 300 to the interposer structure 100. The backside processor bonding pads 318 may be bonded to the front interposer bonding pads 188 via metal-to-metal bonding, such as copper-to-copper bonding. In one embodiment, the backside die dielectric layers 312 of the processor dies 300 may be bonded to surface segments of the interposer dielectric material layers 160 via dielectric-to-dielectric bonding, such as silicon oxide-to-silicon oxide bonding.

As discussed above, the interposer metal interconnect structures 180 may be configured to provide electrical connections to and from a plurality of processor dies 300. Direct data transfer between processing units 320 of different processor dies 300 may be effected using a subset of the interposer metal interconnect structures 180 which function as data buses. Generally, in embodiments in which M processor dies 300 are bonded to an interposer structure 100, the interposer metal interconnect structures 180 may comprise up to M(M−1)/2 sets of data buses configured to function as signal transmission paths to and from the M processor dies 300. Thus, the processing units 320 within the M processor dies 300 may exchange data to and from one another using the data transfer buses within the interposer structure 100.

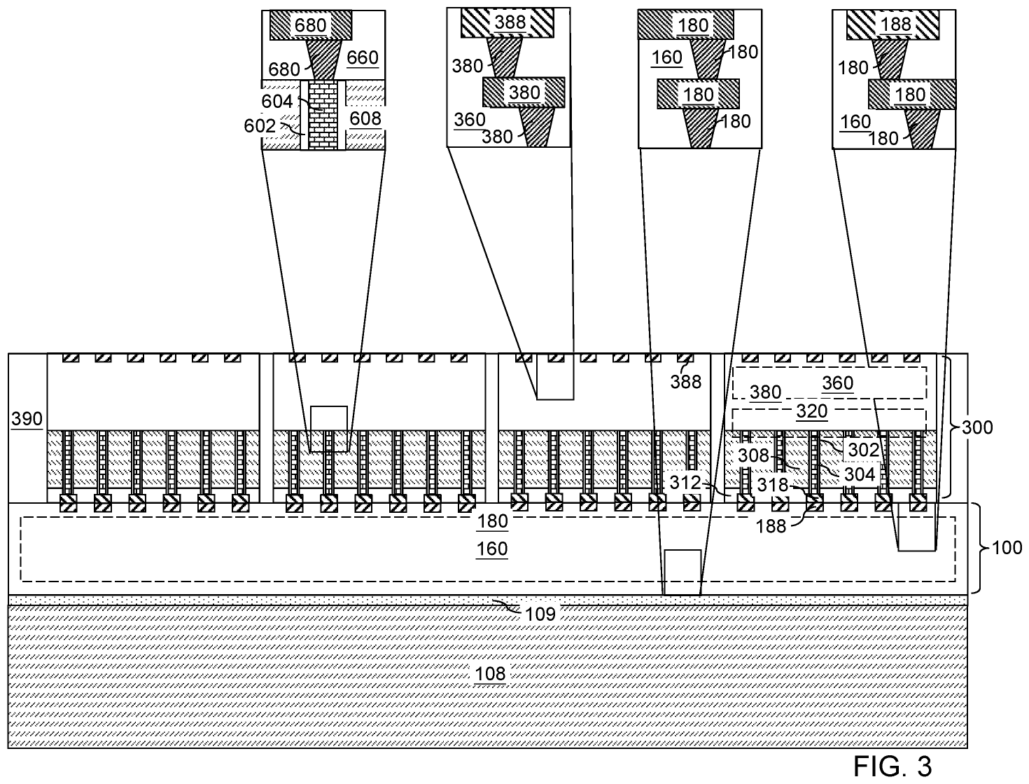

Referring to FIG. 3, a dielectric matrix 390 may be formed by depositing a dielectric material within gaps between neighboring pairs of processor dies 300, and by removing portions of the dielectric material from above the horizontal plane including top surfaces of the plurality of processor dies 300. Remaining portions of the dielectric material filling the gaps comprise the dielectric matrix 390.

In one embodiment, the dielectric material of the dielectric matrix may comprise a molding compound (MC). The MC may comprise an epoxy-containing compound that may be hardened (i.e., cured) to provide a dielectric material portion having sufficient stiffness and mechanical strength. The MC may include epoxy resin, hardener, silica (as a filler material), and other additives. The MC may be provided in a liquid form or in a solid form depending on the viscosity and flowability. Liquid MC typically provides better handling, good flowability, less voids, better fill, and less flow marks. Solid MC typically provides less cure shrinkage, better stand-off, and less die drift. A high filler content (such as 85% in weight) within an MC may shorten the time in mold, lower the mold shrinkage, and reduce the mold warpage. Uniform filler size distribution in the MC may reduce flow marks, and may enhance flowability. Excess portions of the molding compound may be removed from above the horizontal plane including the top surfaces of the processor dies 300.

The MC may be cured at a curing temperature to form a dielectric matrix 390, which is a matrix made of the MC. The dielectric matrix 390 may laterally extend across the entirety of the area of the carrier substrate 108. A reconstituted wafer is thus formed, which includes the carrier substrate 108, a two-dimensional array of interposer structures 100, sets of processor dies 300 bonded to a respective one of the interposer structures 100, and the dielectric matrix 390. Within each area of an interposer structure 100 in a plan view, a plurality of processor dies 300 which are bonded to the interposer structure 100 may be formed within a dielectric matrix 390.

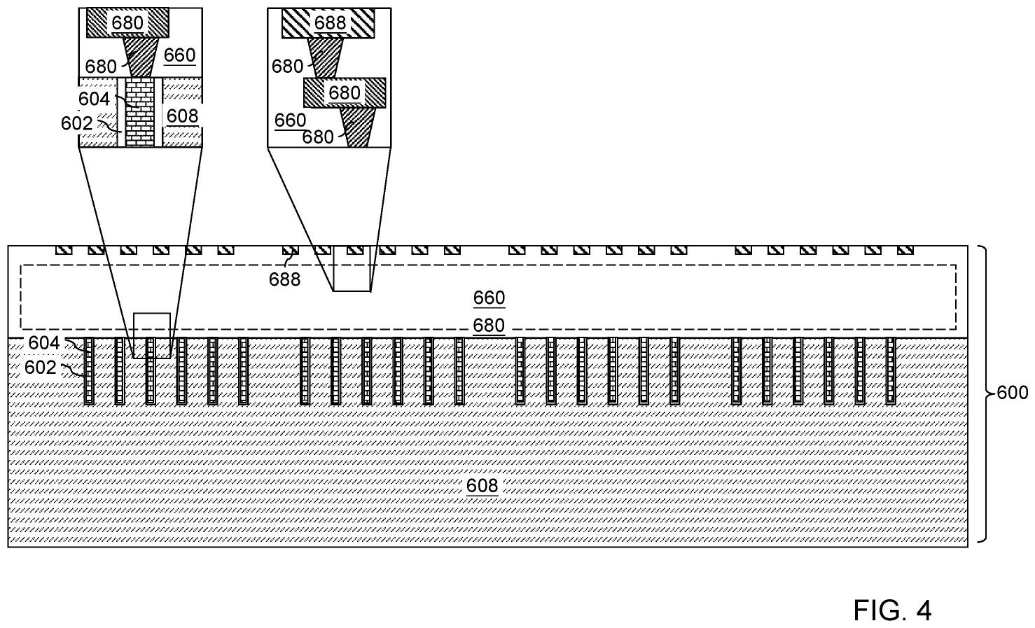

Referring to FIG. 4, a wafer including an array of router dies 600 may be provided. Each router die 600 may have the same area as an interposer structure 100 described with reference to FIGS. 1-3 in a plan view such as a top-down view. The region illustrated in FIG. 4 corresponds to the area of a single router die 600. Generally, a two-dimensional array of router dies 600 may be formed on a router substrate 608, which may be a semiconductor substrate such as a single crystalline silicon substrate. It is understood that instances of a router die 600 be repeated in a two-dimensional array such that a plurality of router dies 600 includes a respective portion of the router substrate 608. The area of each router die 600 may be the same as the area of an interposer structure 100, and may be selected based on the total number of memory dies to be subsequently attached to a router die 600.

Via cavities may be formed in an upper portion of the router substrate 608. For example, a photoresist layer may be applied over the top surface of the router substrate 608, and may be lithographically patterned to form an array of discrete openings. An anisotropic etch process may be performed to transfer the pattern of the discrete openings in the photoresist layer into the upper portion of the router substrate 608. The voids that are formed in the upper portion of the router substrate 608 comprise the via cavities. The depth of the via cavities may be in a range from 5 microns to 30 microns. The lateral dimension (such as a diameter) of each via cavity may be in a range from 1 micron to 10 microns, although lesser and greater lateral dimensions may also be used. The photoresist layer may be subsequently removed, for example, by ashing.

An insulating material may be conformally deposited in peripheral regions of the via cavities in the router substrate 608. The insulating material may comprise a silicon oxide material such as undoped silicate glass or a doped silicate glass. At least one conductive material may be deposited in remaining volumes of the via cavities. The at least one conductive material may comprise, for example, a combination of a metallic barrier material (such as TiN, TaN, WN, and/or MoN) and a metallic fill material such as tungsten or copper. Excess portions of the insulating material and the at least one conductive material may be removed from above the horizontal plane including the top surface of the router substrate 608 by a planarization process, which may use a chemical mechanical polishing (CMP) process and/or a recess etch process. Each remaining portion of the insulating material comprises an insulating spacer, which is referred to as a router insulating spacer 602. Each remaining portion of the at least one conductive material comprises a router through-substrate via structure 604, which is also referred to as a router through-substrate via structure. The router through-substrate via structures 604 do not extend through the entire thickness of the router substrate 608 at this processing step. However, upon subsequent thinning of the backside of the router substrate 608, the router through-substrate via structures 604 may extend through the thinned router substrate 608.

Router dielectric material layers 660 may be subsequently deposited over the router substrate 608. Router metal interconnect structures 680 and front router bonding pads 688 may be formed within router dielectric material layers 660. The router dielectric material layers 660 may comprise interlayer dielectric (ILD) materials as known in the art, which may comprise, for example, undoped silicate glass, a doped silicate glass, silicon nitride, silicon carbide nitride, dielectric metal oxides, etc. In one embodiment, the router dielectric material layers 660 may comprise, and/or may consist essentially of, inorganic dielectric materials. The router metal interconnect structures 680 may comprise metal via structures and metal line structures. In some embodiments, sidewalls of the metal via structures may be tapered such that a lateral dimension (such as a diameter) of each metal via structure increases with a vertical distance from a top surface of the router substrate 608. The total number of levels of the metal line structures may be in a range from 2 to 16, although a greater number of levels may also be used. The router metal interconnect structures 680 may comprise copper, aluminum, tungsten, titanium, or other metals providing high electrical conductivity.

The front router bonding pads 688 may be formed at the topmost level of the router dielectric material layers 660. The topmost dielectric material layer selected from the router dielectric material layers 660 is also referred to as router bonding dielectric layer, and may comprise a dielectric material that may be used for dielectric-to-dielectric bonding such as silicon oxide-to-silicon oxide bonding. In one embodiment, the router bonding dielectric layer may comprise undoped silicate glass or a doped silicate glass. The front router bonding pads 688 may be configured for metal-to-metal bonding such as copper-to-copper bonding. In one embodiment, the front router bonding pads 688 may comprise copper bonding pads having copper surfaces as bonding surfaces.

The front router bonding pads 688 may be arranged as multiple arrays each having a respective pitch along repetition directions. Generally, the pattern of each array of front router bonding pads 688 may be a mirror image pattern of the pattern of front processor bonding pads 388 of processor dies 300 described with reference to FIG. 2. According to an aspect of the present disclosure, the pattern of the front router bonding pads 688 may be a mirror image pattern of the pattern of the front processor bonding pads 388 of the processor dies 300 located within the assembly of an interposer structure 100 and a plurality of processor dies 300 as provided in the exemplary structure of FIG. 3.

Generally, the router metal interconnect structures 680 provide electrically conductive paths between each array of router through-substrate via structures 604 and each array of front router bonding pads 688. Specifically, each array of router through-substrate via structures 604 configured to be electrically connected to a respective memory die in a subsequent processing step comprises a plurality of groups of router through-substrate via structures 604. Each array of front router bonding pads 688 may comprise a plurality of groups of front router bonding pads 688. Each group of front router bonding pads 688 may be electrically connected to a respective group of router through-substrate via structure 604.

In one embodiment, the front router bonding pads 688 within a router die 600 may comprise M arrays of front router bonding pads 688. The integer M may be the total number of processor dies 300 to be bonded to the router die 600. The integer M may be in a range from 2 to 2⁶. The router through-substrate via structures 604 within a router die 600 may comprise N arrays of router through-substrate via structures 604. The integer N may be the total number of memory dies to be subsequently bonded to the router die 600. The integer N may be in a range from 2 to 2⁶.

In one embodiment, each array of front router bonding pads 688 selected from the M arrays of front router bonding pads 688 may comprise N groups of front router bonding pads 688. In one embodiment, each array of router through-substrate via structures 604 selected from the N arrays of router through-substrate via structures 604 may comprise M groups of router through-substrate via structures 604. In one embodiment, a total of M×N groups of front router bonding pads 688 may be provided, and a total of M×N groups of router through-substrate via structures 604 may be provided. In one embodiment, each group of front router bonding pads 688 selected from the M×N groups of front router bonding pads 688 may be electrically connected to a respective group of router through-substrate via structures 604 selected from the M×N groups of router through-substrate via structures 604.

In one embodiment, for each selected combination of an array of front router bonding pads 688 and an array of router through-substrate via structures 604, electrical connections which may include a respective subset of the router metal interconnect structures 680 is provided between a group of front router bonding pads 688 within the selected array of front router bonding pads 688 and a group of router through-substrate via structures 604 within the selected array of router through-substrate via structures 604.

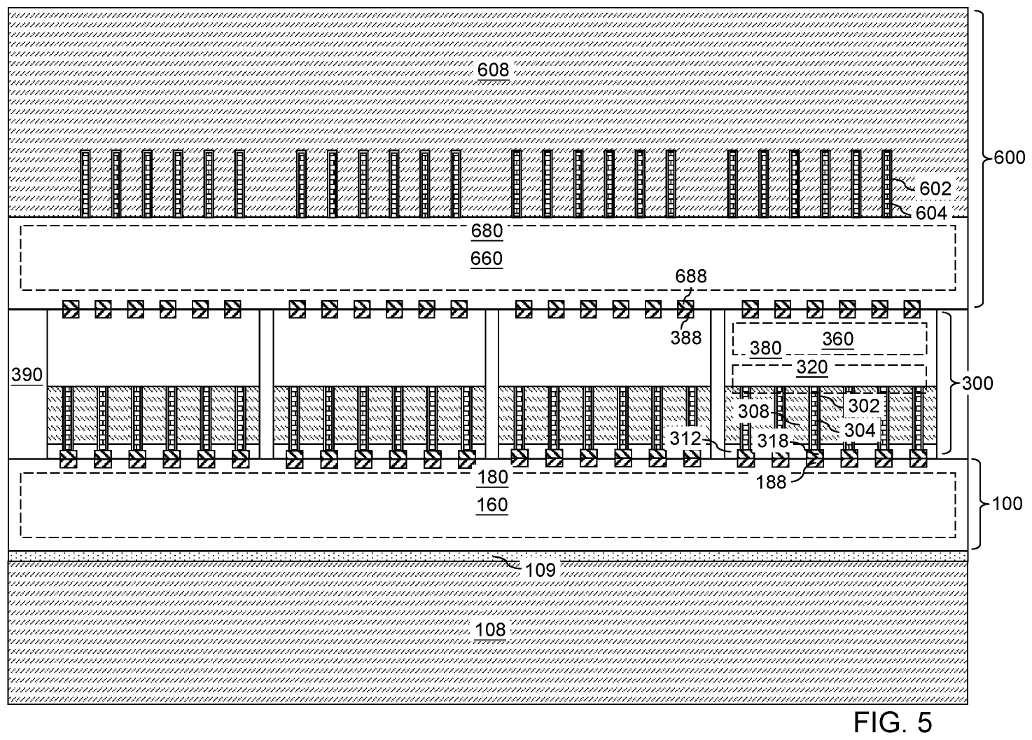

Referring to FIG. 5, the wafer including a two-dimensional array of router dies 600 may be bonded to the wafer including a bonded assembly of a two-dimensional array of interposer structures 100 and a two-dimensional array of sets of processor dies 300 by wafer-to-wafer bonding. Specifically, the front router bonding pads 688 of each router die 600 are bonded to first processor bonding pads (such as front processor bonding pads 388) within a plurality of processor dies 300 which is bonded to a respective interposer structure 100. The front router bonding pads 688 are formed within the router dielectric material layers 660 within each router die 600. The front processor bonding pads 388 of the plurality of processor dies 300 are formed within the die dielectric material layers 360 of the plurality of processor dies 300.

Each router die 600 may be attached to a respective interposer structure 100 via a respective plurality of processor dies 300 which is located entirely within the area of the router die 600. In one embodiment, each router die 600 may have the same area as a respective underlying interposer structure 100. Each router die 600 comprises router dielectric material layers 660 having formed therein router metal interconnect structures 680 and a router substrate 608 having formed therein router through-substrate via structures 604. Each of the plurality of processor dies 300 comprises a respective set of die dielectric material layers 360 having formed therein a respective set of die metal interconnect structures 380 and a respective set of front processor bonding pads 388. The router dielectric material layers 660 have front router bonding pads 688 formed therein.

Within each area of a router die 600, the front router bonding pads 688 are electrically connected to a respective one of the front processor bonding pads 388 upon attaching the router die 600 to the plurality of processor dies 300. In one embodiment, each router die 600 may be attached to the plurality of processor dies 300 is by performing a hybrid bonding process, which is a combination of a metal-to-metal bonding process to and from bonding pads and a dielectric-to-dielectric bonding process to dielectric surfaces. In one embodiment, the front router bonding pads 688 are bonded to the front processor bonding pads 388 via metal-to-metal bonding, such as copper-to-copper bonding. The surfaces of the die dielectric material layers 360 are bonded to surface segments of the interposer dielectric material layers 160 via dielectric-to-dielectric bonding such as silicon oxide-to-silicon oxide bonding. Alternatively, the two-dimensional array of router dies 600 may be bonded to the two-dimensional array of sets of processor dies 300 via microbump bonding (also known as C2 bonding or chip connection bonding), C4 (controlled collapse chip connection) bonding, or alternative chip attachment methods.

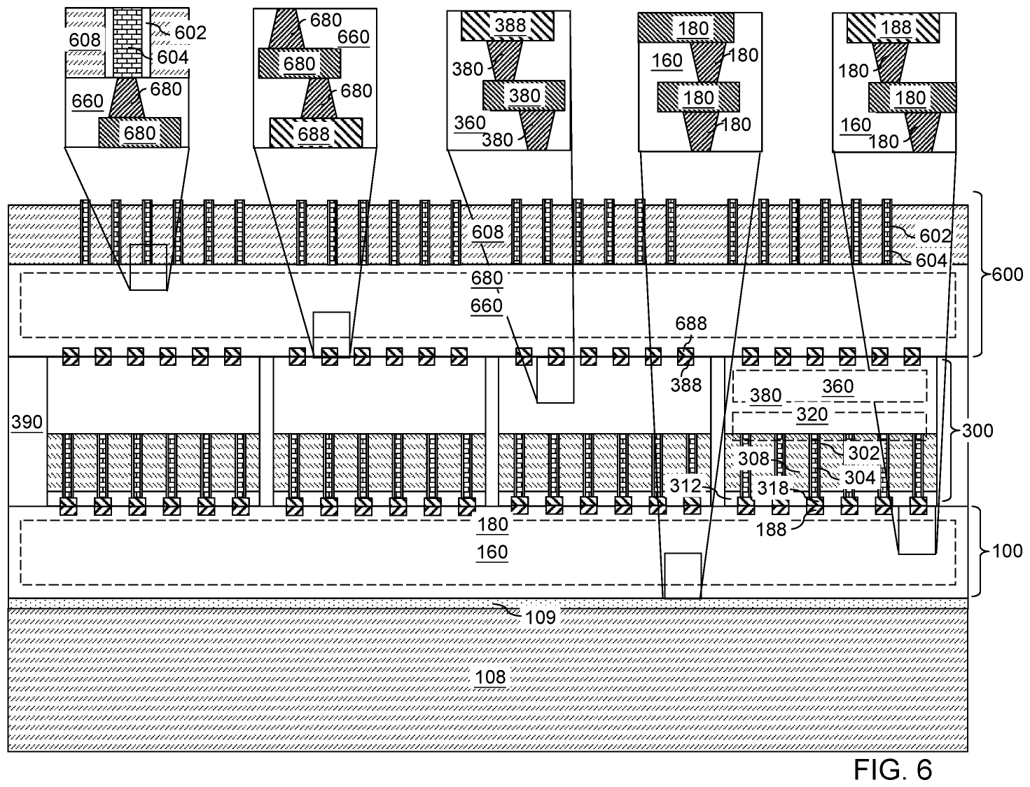

Referring to FIG. 6, the backside of the router substrate 608 may be thinned, for example, by grinding, polishing, an anisotropic etch process, an isotropic etch process, or a combination thereof. A terminal step of the thinning process that thins the backside of the router substrate 608 may comprise a chemical mechanical polishing step that uses the router through-substrate via structures 604 as stopping structures. The backside end surfaces of the router through-substrate via structures 604 are exposed after thinning the backside of the router substrate 608. A recess etch process may be optionally performed to vertically recess the physically exposed backside surface of the router substrate 608.

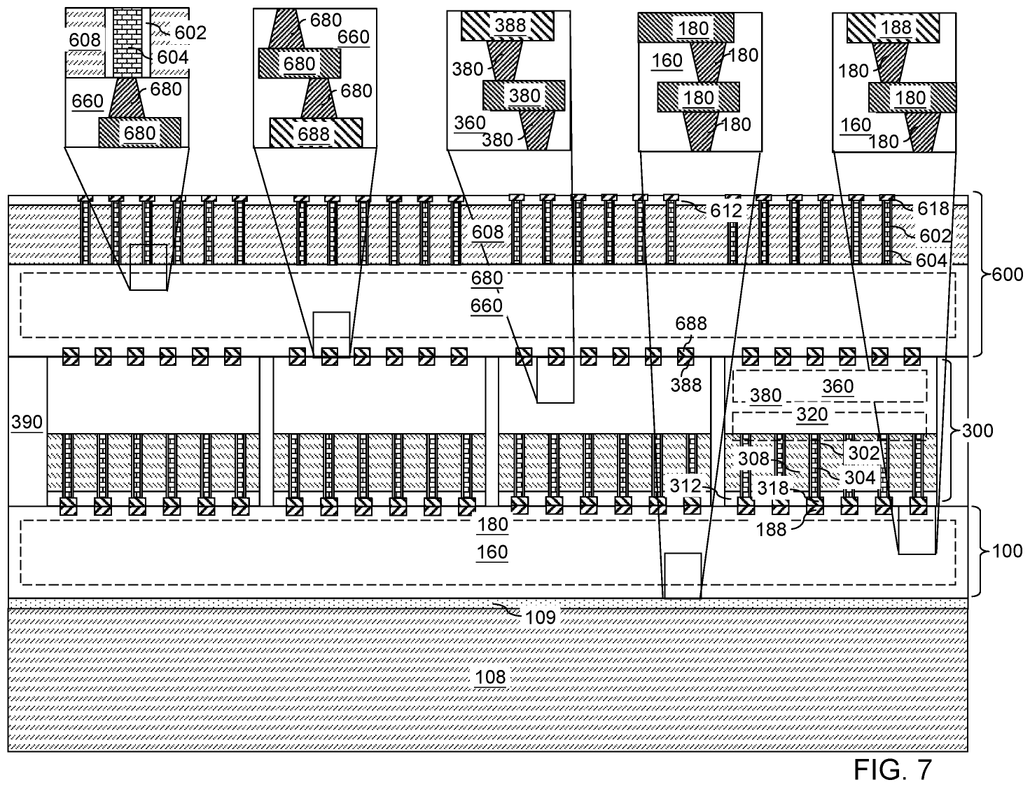

Referring to FIG. 7, a backside router dielectric layer 612 may be deposited on the physically exposed backside surface of the router substrate 608. The backside router dielectric layer 612 may comprise a dielectric material that may be used for dielectric-to-dielectric bonding such as silicon oxide-to-silicon oxide bonding. The thickness of the backside router dielectric layer 612 may be in a range from 100 nm to 600 nm, although lesser and greater thicknesses may also be used. Pad cavities may be formed in the backside router dielectric layer 612 over the areas of the router through-substrate via structures 604, and end surfaces of the router through-substrate via structures 604 may be physically exposed underneath the pad cavities. At least one conductive material may be deposited in the pad cavities, and excess portions of the at least one conductive material may be removed from above the horizontal plane including the top surface of the backside router dielectric layer 612. The at least one conductive material may comprise a combination of a metallic barrier material (such as TiN, TaN, WN, and/or MoN) and a metallic fill material such as copper. Each remaining portion of the at least one conductive material filling a pad cavity constitutes a backside router bonding pad 618.

The backside router bonding pads 618 within the area of an interposer structure 100 may be arranged as arrays of backside router bonding pads 618. As discussed above, the router through-substrate via structures 604 within a router die 600 may comprise N arrays of router through-substrate via structures 604. The integer N may be the total number of memory dies to be subsequently bonded to the router die 600. The integer N may be in a range from 2 to 2⁶. In this embodiment, the backside router bonding pads 618 within a router die 600 may comprise N arrays of backside router bonding pads 618. The backside router bonding pads 618 may be configured for metal-to-metal bonding, such as copper-to-copper bonding.

Alternatively, the backside router bonding pads 618 may be configured for C4 bonding. In this embodiment, each of the backside router bonding pads 618 may comprise a layer stack including a metallic nitride barrier liner comprising a conductive metallic nitride material (such as TiN, TaN, WN, or MoN), a copper layer, an adhesion layer enhancing the adhesion strength of subsequently deposited layers and comprising a material such as Cr, Ti, or a Cr/Ti alloy, a metallic barrier layer comprising a diffusion barrier metallic material such as W, Mo, or Mo, and an under-bump metallization (UBM) layer. The UBM layer may comprise a multi-layer stack such as a layer stack of a copper layer, a nickel layer, and a gold layer. Alternative UBM layer compositions may also be used.

Generally, the router die 600 comprises a backside router dielectric layer 612 located on a backside surface of the router substrate 608 and backside router bonding pads 618 formed therein. The backside router bonding pads 618 are in contact with end surfaces of the router through-substrate via structures 604.

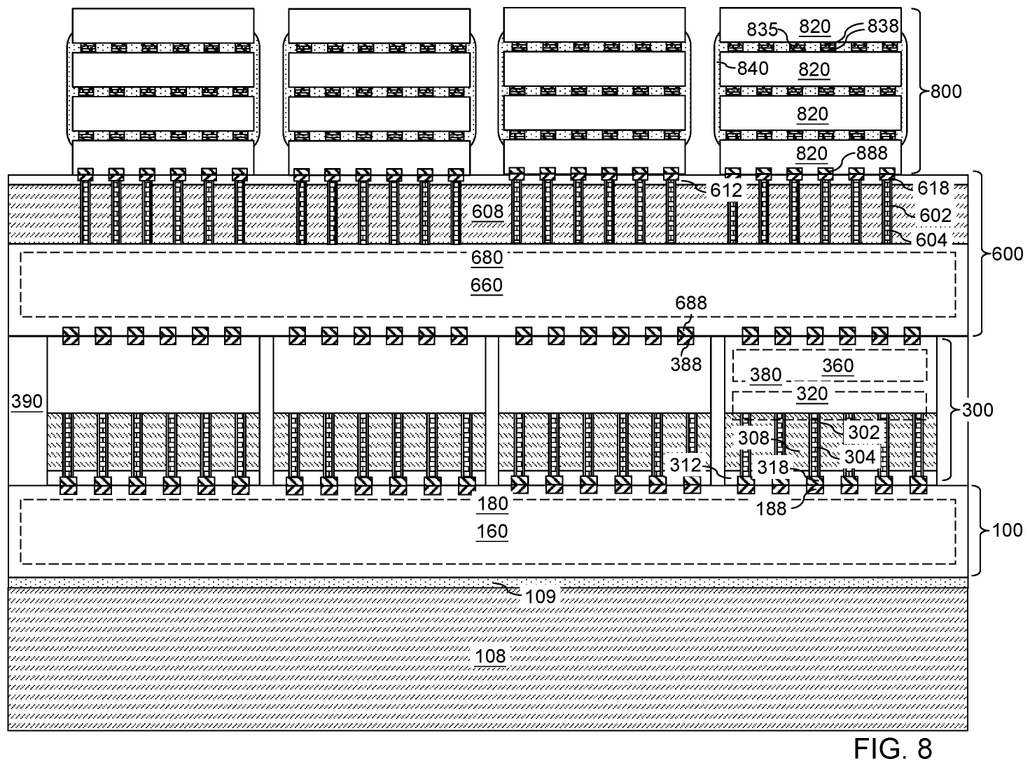

Referring to FIG. 8, memory dies 800 may be bonded to the backside of the router die 600. Each memory die 800 may comprise bonding pads arranged in a mirror image pattern of the pattern of an array of backside router bonding pads 618. The bonding pads of the memory dies 800 are herein referred to as memory-die bonding pads 888. The memory-die bonding pads 888 may be bonded to the backside router bonding pads 618 by metal-to-metal bonding (such as copper-to-copper bonding) or by solder bonding (such as microbump bonding, i.e., chip connection bonding). If the backside router bonding pads 618 within a router die 600 comprise N arrays of backside router bonding pads 618, N memory dies 800 may be bonded to the N arrays of backside router bonding pads 618. The memory-die bonding pads 888 of the memory dies 800 are electrically connected to the router through-substrate via structures 604.

In one embodiment, the memory dies 800 comprise high-bandwidth memory (HBM) memory dies 800 including a respective vertical stack of dynamic random access memory (DRAM) dies 820 that are interconnected to one another by chip connection (C2) bonding. Each chip connection bonding may use a pair of arrays of microbump structures 838 that are connected to each other by an array of solder material portion 835. Each microbump structure 838 may comprise a metallic pillar structure that comprises a vertical layer stack including a metallic nitride barrier liner comprising a conductive metallic nitride material (such as TiN, TaN, WN, or MoN), a copper layer, an adhesion layer enhancing the adhesion strength of subsequently deposited layers and comprising a material such as Cr, Ti, or a Cr/Ti alloy, a metallic barrier layer comprising a diffusion barrier metallic material such as W, Mo, or Mo, and an under-bump metallization (UBM) layer. A molding compound encapsulation structure 840 may be provided such that the microbump structures 838 and the solder material portions 835 are encapsulated by the molding compound encapsulation structure 840.

The memory-die bonding pads 888 may be configured for metal-to-metal bonding, or for solder bonding. In embodiments in which the memory-die bonding pads 888 are configured for metal-to-metal bonding, each of the memory-die bonding pads 888 may comprise a layer stack including a metallic barrier nitride liner including a conductive metallic nitride material (such as TiN, TaN, WN, and/or MoN) and a copper layer. In this embodiment, copper surfaces of the memory-die bonding pads 888 may be bonded to copper surfaces of the backside router bonding pads 618 by metal-to-metal bonding, which is copper-to-copper bonding. In addition, the bottommost surface of each memory die 800 may comprise a dielectric material (such as silicon oxide) that may be used for dielectric-to-dielectric bonding. In this embodiment, dielectric-to-dielectric bonding may be provided between the bottommost surfaces of the memory dies 800 and the backside router dielectric layer 612.

Alternatively, in embodiments in which the memory-die bonding pads 888 and the backside router bonding pads 618 are configured for solder bonding (such as chip connection bonding), each of the memory-die bonding pads 888 and the backside router bonding pads 618 may comprise a respective microbump structure which may include a metallic pillar structure that comprises a vertical layer stack including a metallic nitride barrier liner comprising a conductive metallic nitride material (such as TiN, TaN, WN, or MoN), a copper layer, an adhesion layer enhancing the adhesion strength of subsequently deposited layers and comprising a material such as Cr, Ti, or a Cr/Ti alloy, a metallic barrier layer comprising a diffusion barrier metallic material such as W, Mo, or Mo, and an under-bump metallization (UBM) layer. In this embodiment, solder material portions (not illustrated) may be used to provide chip connection (C2) bonding (which is also referred to as microbump bonding) between the memory dies 800 and the router die 600.

Generally, the memory dies 800 comprising bonding pads, i.e., memory-die bonding pads 888, that are electrically connected to the router through-substrate via structures 604. In one embodiment, the memory dies 800 comprise memory-die bonding pads 888 that are electrically connected to the router through-substrate via structures 604. In one embodiment, the memory-die bonding pads 888 are bonded to the backside router bonding pads 618 via metal-to-metal bonding. A reconstituted wafer including a carrier substrate 108, a two-dimensional array of interposer structures 100, a two-dimensional array of sets of M processor dies 300, a two-dimensional array of router dies 600, and a two-dimensional array of sets of N memory dies 800 is provided.

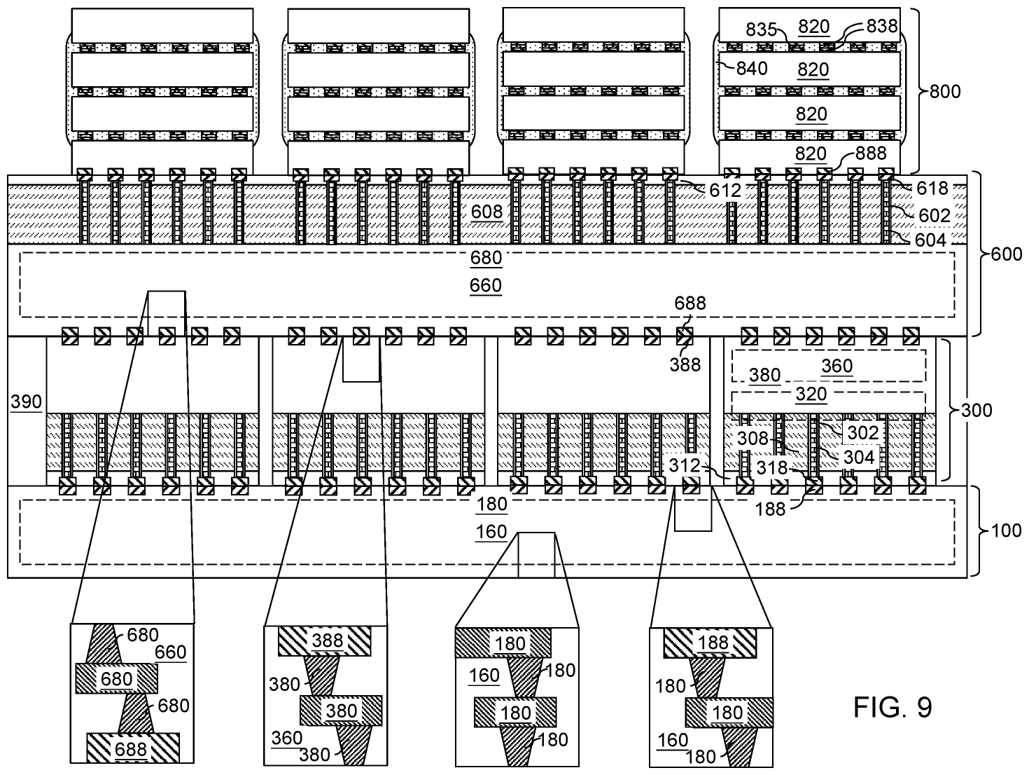

Referring to FIG. 9, the carrier substrate 108 may be detached from the assembly comprising the two-dimensional array of interposer structures 100, the two-dimensional array of sets of M processor dies 300, the two-dimensional array of router dies 600, and the two-dimensional array of sets of N memory dies 800. For example, the carrier substrate 108 may be cleaved by decomposing the interfacial material layer 109 if the interfacial material layer 109 comprises a decomposable material that may be decomposed upon thermal activation or by other means. Alternatively, the carrier substrate 108 may be removed by grinding or polishing. Any residual portion of the interfacial material layer 109 may be subsequently removed by performing a suitable cleaning process.

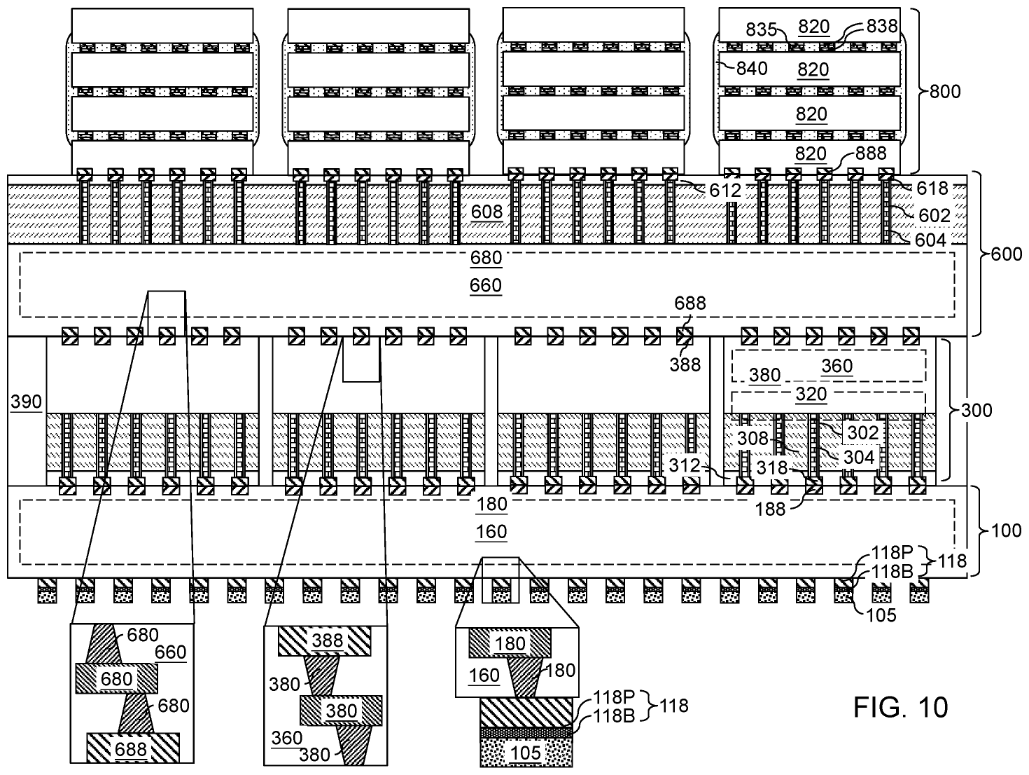

Referring to FIG. 10, bump structures may be formed on the backside surface of the interposer structures 100. In one embodiment, the bump structures may comprise backside interposer bonding pads 118 and solder material portions 105. In this embodiment, each backside interposer bonding pad 118 may comprise a stack of a metallic pad structure 118P and a metallic bump layer 118B. Each metallic pad structure 118P may comprise a stack of a metallic nitride barrier liner comprising a conductive metallic nitride material (such as TiN, TaN, WN, or MoN) and a copper pad structure. Each metallic bump layer 118B may comprise a stack of an adhesion layer enhancing the adhesion strength of subsequently deposited layers and comprising a material such as Cr, Ti, or a Cr/Ti alloy, a metallic barrier layer comprising a diffusion barrier metallic material such as W, Mo, or Mo, and an under-bump metallization (UBM) layer. Alternatively, the bump structures on the backside surface of the interposer structures 100 may comprise alternative bump structures such as metal pads (e.g., copper pads) that are configured for direct metal-to-metal bonding. The bump structures on the backside surface of the interposer structures 100 may, or may not, be configured for hybrid bonding. In embodiments in which the bump structures on the backside surface of the interposer structures 100 are configured for hybrid bonding, the bump structures may be embedded in the interposer dielectric material layers 160 such that physically exposed surfaces of the metal pads are substantially coplanar with the backside surface of the interposer dielectric material layers 160.

Subsequently, the assembly comprising the two-dimensional array of interposer structures 100, the two-dimensional array of sets of M processor dies 300, the two-dimensional array of router dies 600, the two-dimensional array of sets of N memory dies 800, and the backside interposer bonding pads 118 may be diced along dicing channels. The dicing channels correspond to boundaries between neighboring pairs of interposer structures 100, which coincide with boundaries between neighboring pairs of router dies 600 in a plan view such as a top-down view. Each diced portion of the assembly comprises a semiconductor assembly including an interposer structure 100, a set of M processor dies 300, a router die 600, and a set of N memory dies 800. Physically exposed sidewalls of the interposer structure 100, the router die 600, and the dielectric matrix 390 within each semiconductor assembly may be vertically coincident to one another. As used herein, a first surface and a second surface are vertically coincident with each other if the second surface overlies or underlies the first surface and if the first surface and the second surface are located within a same vertical plane.

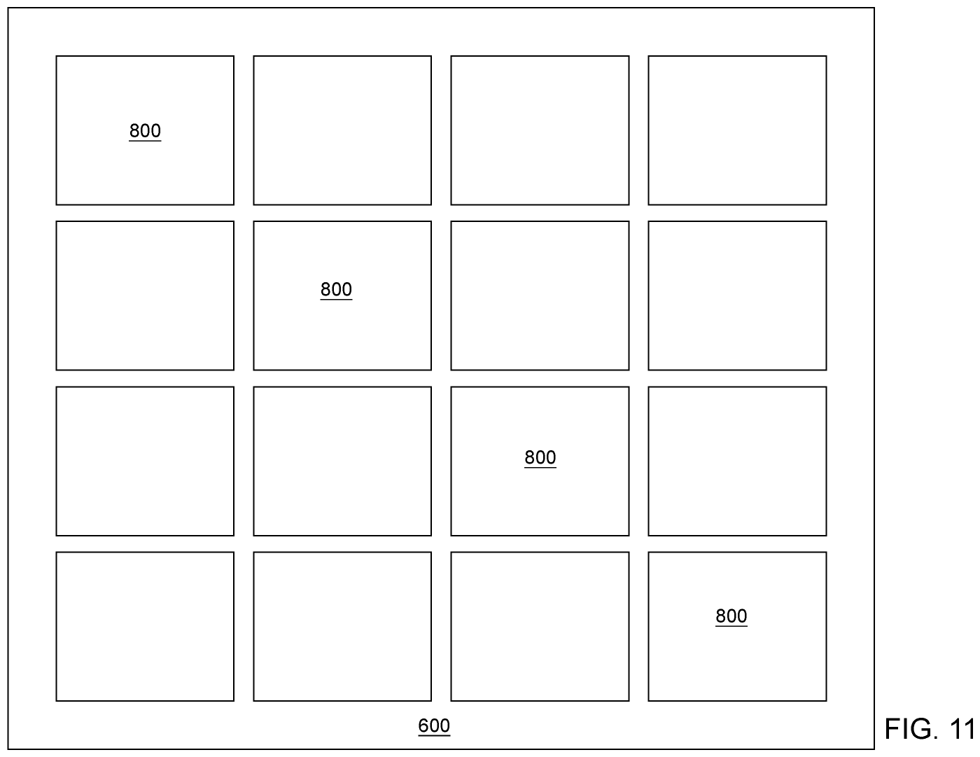

Referring to FIG. 11, a semiconductor assembly formed by dicing of the reconstituted wafer is illustrated. In the illustrated example, the number N of memory dies 800 that are attached to a router die 600 is 2⁴, i.e., 16.

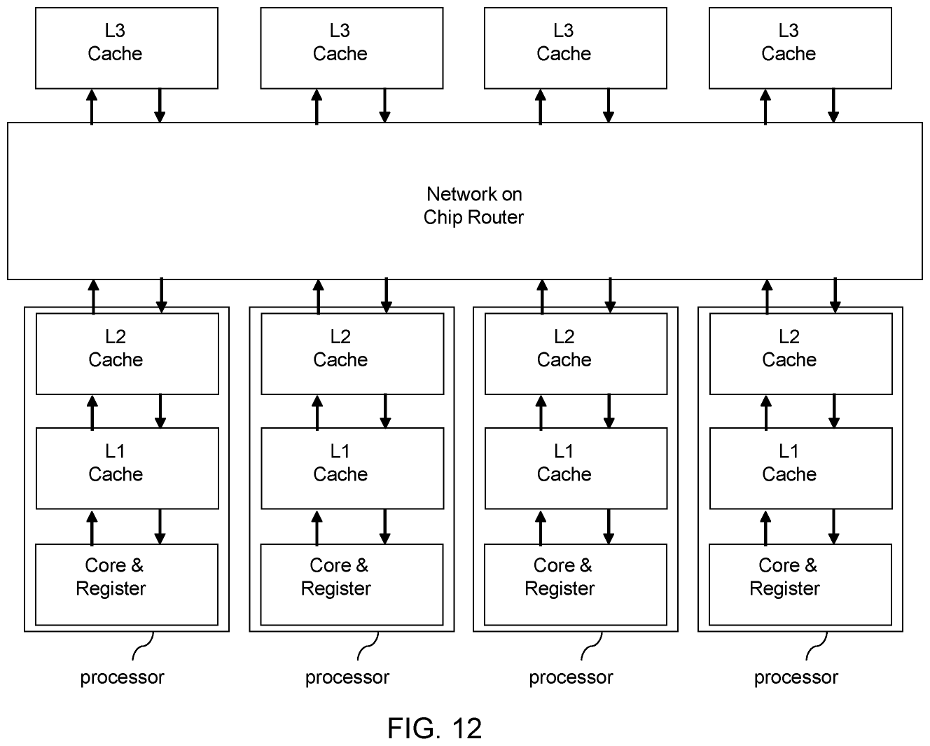

FIG. 12 is a circuit schematic that illustrates operation of a semiconductor assembly illustrated in FIGS. 10 and 11. Each processor die 300 may comprise a processing unit, which comprises a combination of a core and a register. Each processor die 300 may further comprise an L1 cache (i.e., a first-level cache) and an L2 cache (i.e., second-level cache) in communication with the processing unit. M processor dies may be electrically connected to the router die 600, which functions as a network-on-chip router, i.e., a chip that provides a network connection to the processor dies 300 and the memory dies 800. The memory dies 800 may function as L3 caches (i.e., third-level caches), which may be accessed by each of the processor dies 300 through the router die 600.

Generally, the router die 600 may be a passive router die that does not include switching devices therein. Thus, activation of electrical connections between a processor die 300 and a memory die 800 may be controlled by input/output control circuits of the processor die 300. As discussed above, in embodiments in which M processor dies 300 and N memory dies 800 are connected to one another through the router metal interconnect structures 680, M×N sets of electrical connections may be provided between M arrays of front router bonding pads 688 and N arrays of backside router bonding pads 618.

In one embodiment, the M×N sets of electrical connections may be electrically isolated from one another. Alternatively, the M×N sets of electrical connections may comprise a set of electrical signal pathways that are shared with a plurality of arrays of front router bonding pads 688, or shared with a plurality of arrays of backside router bonding pads 618. In this embodiment, input/output control devices in the processor dies 300 or in the memory dies 800 may electrically disconnect inactive signal paths by setting the state of the input/output control devices of unselected processor dies 300 and/or unselected memory dies 800 at a high-impedance state, i.e., a disconnection state. Thus, data transfer between the M processor dies 300 and the N memory dies 800 may be effected through the router die 600 without use of any intermediate switching device.

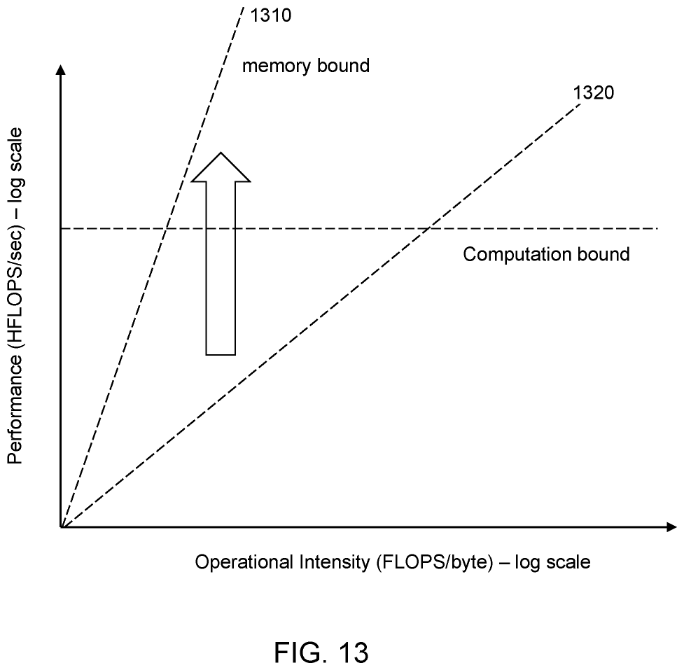

The bandwidth for data transfer as provided by the router die 600 of the present disclosure may be wider than bandwidths provided by previously known data transfer schemes between processor dies and memory dies. FIG. 13 schematically illustrates a change in the operating regime of a computing device which may include the semiconductor assembly of the present disclosure relative to previously known computing devices. Generally, performance of a computing system may be computation bound, i.e., limited by the performance of processing units, or memory bound, i.e., limited by the data transfer speed from the memory dies to the processor dies. Curve 1310 represents a limitation on the performance (as measured in gigaflops per second) due to a memory wall problem in prior art computing systems. Curve 1320 represents a limitation on the performance in a system using a semiconductor assembly described with reference to FIGS. 10 and 11. The semiconductor assembly of the present disclosure may provide the highest level of performance that is limited only by the performance of the processing units 320 with a lower operational intensity (as measured in flops per byte) for the processing units 320. This mode of operation consumes less power, generates less heat, and provides the highest possible performance level through increase in the bandwidth for data transmission between the memory dies 800 and the processor dies 300.

In embodiments in which the memory dies 800 comprise high-bandwidth memory dies, it is estimated that the router through-substrate via structures 604 may be formed with a pitch in a range from 10 microns to 60 microns, such as from 20 microns to 40 microns. The area of a keep-out zone (KOZ) for the router through-substrate via structures 604 may be in a range from 1% to 10% of the total area of the router die 600 in a plan view such as a top-down view. The memory dies 800 may be arranged in a rectangular periodic array, or may be arranged in a staggered pattern or in any other ground-up design pattern that is optimized for performance based on the arrangement of the processor dies 300.

The architecture provided by the bonded assembly of an interposer, M processor dies 300, a router die 600, and N memory dies may increase the total memory capacity, and may decrease the memory latency, which results in the shift in the roof line (such as curve 1310 or 1320) in a computing power graph as illustrated in FIG. 13. The total number N of memory dies 800 that may be attached to a router die 600 generally depends on the area of the router die 600, which may be the same as the area of the interposer structure 100. In embodiments in which the router die 600 has a size of about three retiles (which corresponds to an area of about 3 times 30 mm×30 mm), up to 20 high-bandwidth memory (HBM) dies may be attached to the router die 600 as memory dies 800. The memory capacity per memory die 800 and the total number of memory dies 800 may be increased to provide an increase in the memory capacity for a computing system, and utilization of the increased memory capacity may be effected through the data paths provided within the router die 600.

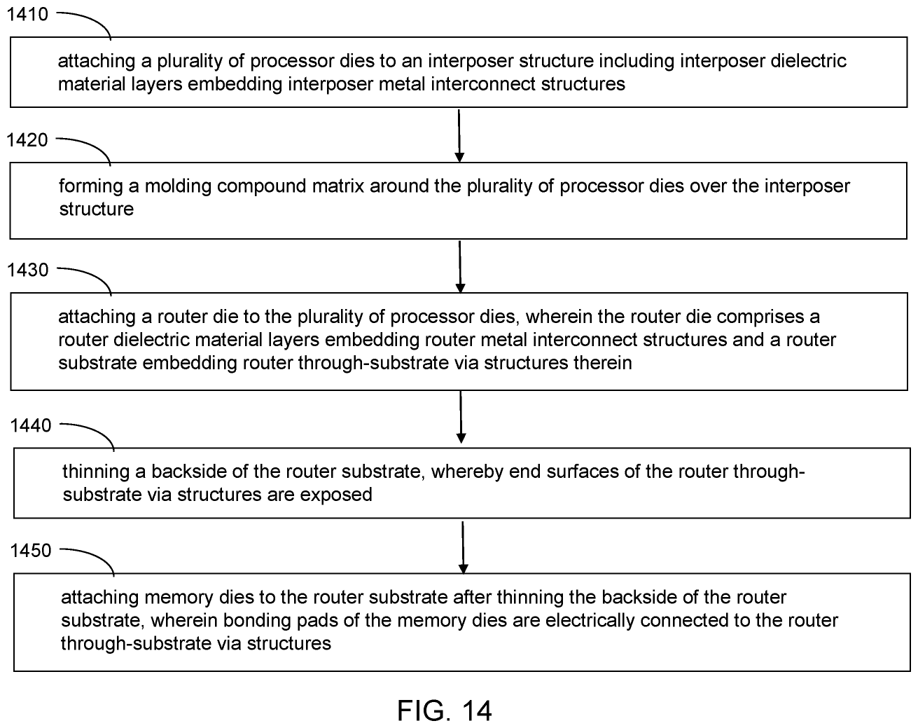

Referring to FIG. 14, a flowchart illustrating general processing steps for forming a semiconductor assembly of the present disclosure is illustrated.

Referring to step 1410 and FIGS. 1 and 2, a plurality of processor dies 300 may be attached to an interposer structure 100 including interposer dielectric material layers 160 having formed therein interposer metal interconnect structures 180.

Referring to step 1420 and FIG. 3, a dielectric matrix 390 may be formed around the plurality of processor dies 300 over the interposer structure 100.

Referring to step 1430 and FIGS. 4 and 5, a router die 600 may be attached to the plurality of processor dies 300. The router die 600 comprises router dielectric material layers 660 having formed therein router metal interconnect structures 680 and a router substrate 608 having router through-substrate via structures 604 formed therein.

Referring to step 1440 and FIGS. 6 and 7, a backside of the router substrate 608 may be thinned. End surfaces of the router through-substrate via structures 604 are exposed.

Referring to step 1450 and FIGS. 8-11, memory dies 800 may be attached to the router substrate 608 after thinning the backside of the router substrate 608. Bonding pads of the memory dies 800, i.e., memory-die bonding pads 888, are electrically connected to the router through-substrate via structures 604.

Referring to all drawings and according to various embodiments of the present disclosure, a semiconductor assembly is provided, which comprises: a plurality of processor dies 300 bonded to an interposer structure 100 including interposer dielectric material layers 160 having formed therein interposer metal interconnect structures 180; a dielectric matrix 390 laterally surrounding the plurality of processor dies 300; a router die 600 bonded to the plurality of processor dies 300 and comprising router dielectric material layers 660 having formed therein router metal interconnect structures 680 and router substrate 608 having formed therein router through-substrate via structures 604 therein; and memory dies 800 comprising bonding pads (i.e., the memory-die bonding pads 888) that are electrically connected to the router through-substrate via structures 604.

In one embodiment, the plurality of processor dies 300 comprises: processor-die substrates 308 having formed therein die through-substrate via structures 304; and backside processor bonding pads 318 located on the die through-substrate via structures 304 and bonded to front interposer bonding pads 188 formed within the interposer dielectric material layers 160 of the interposer structure 100.

In one embodiment, the plurality of processor dies 300 comprises backside die dielectric layers 312 laterally surrounding the: and surfaces of the backside die dielectric layers 312 are bonded to surface segments of the interposer dielectric material layers 160 via dielectric-to-dielectric bonding. In one embodiment, sidewalls of the interposer structure 100 are vertically coincident with sidewalls of the router die 600. In one embodiment, front router bonding pads 688 which are formed within the router dielectric material layers 660 are bonded to front processor bonding pads 388 which are formed within the die dielectric material layers 360 of the plurality of processor dies 300.

According to another aspect of the present disclosure, a semiconductor assembly is provided, which comprises: an interposer structure 100 comprising interposer dielectric material layers 160 having formed therein interposer metal interconnect structures 180 and front interposer bonding pads 188; a plurality of processor dies 300 embedded within a dielectric matrix 390 and comprising first processor bonding pads (such as backside processor bonding pads 318) that are bonded to the front interposer bonding pads 188; a router die 600 comprising router dielectric material layers 660 having formed therein router metal interconnect structures 680 and front router bonding pads 688 and further comprising router substrate 608 having formed therein router through-substrate via structures 604, wherein the front router bonding pads 688 are bonded to first processor bonding pads (such as front processor bonding pads 388) within the plurality of processor dies 300; and memory dies 800 that are bonded to router die 600, wherein the memory dies 800 comprise memory-die bonding pads 888 that are electrically connected to the router through-substrate via structures 604.

In one embodiment, the router die 600 comprises a backside router dielectric layer 612 located on a backside surface of the router substrate 608 and having formed therein backside router bonding pads 618 which are in contact with end surfaces of the router through-substrate via structures 604. In one embodiment, the memory dies 800 comprise bonding pads (i.e., memory-die bonding pads 888) which are bonded to the backside router bonding pads 618 via metal-to-metal bonding.

In one embodiment, sidewalls of the router die 600 are vertically coincident with sidewalls of the dielectric matrix 390. In one embodiment, the plurality of processor dies 300 comprises die dielectric material layers 360 having formed therein die metal interconnect structures and front processor bonding pads 388; the router dielectric material layers 660 have front router bonding pads 688 formed therein; and the front router bonding pads 688 are bonded to the front processor bonding pads 388 via metal-to-metal bonding.

Embodiments of the present disclosure may be used to provide a computing system using a passive router die to provide an increased bandwidth between processor dies 300 and memory dies 800. For example, high-bandwidth memory (HBM) dies (as used as the memory dies 800) may be integrated with application specific integrated circuit (ASIC) dies (as used as processor dies 300) to provide a computing system having enhanced computing performance. The router die 600 functions as a network-on-chip (NoC) die which provides data paths for the HBM dies, and the data flow may be controlled by the ASIC dies. The computing system of the present disclosure may be manufactured using Chip-on-Wafer-on-Substrate (CoWoS) technology which utilizes through-substrate via structures and hybrid bonding. The processor dies 300 may include any type of processing units, and thus, may be any type of processor die known in the art.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “may” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “may” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor assembly comprising:
attaching a plurality of processor dies to an interposer structure including interposer dielectric material layers having formed therein interposer metal interconnect structures;
forming a dielectric matrix around the plurality of processor dies over the interposer structure;
attaching a router die to the plurality of processor dies, wherein the router die comprises router dielectric material layers having formed therein router metal interconnect structures and a router substrate having router through-substrate via structures formed therein;
thinning a backside of the router substrate, whereby end surfaces of the router through-substrate via structures are exposed; and
attaching memory dies to the router substrate after thinning the backside of the router substrate, wherein bonding pads of the memory dies are electrically connected to the router through-substrate via structures.

2. The method of claim 1, wherein:
the interposer structure comprises front interposer bonding pads formed within the interposer dielectric material layers;
the plurality of processor dies comprises processor-die substrates having formed therein die through-substrate via structures; and
the through-substrate via structures are electrically connected to the front interposer bonding pads upon attaching the plurality of processor dies to the interposer structure.

3. The method of claim 2, wherein:
the plurality of processor dies comprises backside processor bonding pads located on the die through-substrate via structures; and
the backside processor bonding pads are bonded to the front interposer bonding pads via metal-to-metal bonding upon attaching the plurality of processor dies to the interposer structure.

4. The method of claim 3, wherein:
the plurality of processor dies comprises backside die dielectric layers laterally surrounding a respective subset of the backside processor bonding pads; and
the backside die dielectric layers are bonded to surface segments of the interposer dielectric material layers via dielectric-to-dielectric bonding.

5. The method of claim 1, wherein:
the interposer structure is provided on a top surface of a carrier substrate; and
the method comprises detaching the carrier substrate from an assembly comprising the interposer structure, the plurality of processor dies, and the router substrate after thinning the backside of the router substrate.

6. The method of claim 1, wherein:
each of the plurality of processor dies comprises a respective set of die dielectric material layers having formed therein a respective set of die metal interconnect structures and a respective set of front processor bonding pads;
the router dielectric material layers having formed therein front router bonding pads; and
the front router bonding pads are electrically connected to a respective one of the front processor bonding pads upon attaching the router die to the plurality of processor dies.

7. The method of claim 6, wherein the router die is attached to the plurality of processor dies is by performing a hybrid bonding process such that:
the front router bonding pads are bonded to the respective one of the front processor bonding pads via metal-to-metal bonding; and
surfaces of the die dielectric material layers are bonded to surface segments of the interposer dielectric material layers via dielectric-to-dielectric bonding.

8. The method of claim 1, wherein the dielectric matrix is formed by:
depositing a dielectric material within gaps between neighboring pairs of processor dies selected from the plurality of processor dies; and
removing portions of the dielectric material from above a horizontal plane including top surfaces of the plurality of processor dies, wherein remaining portions of the dielectric material filling the gaps comprise the dielectric matrix.

9. The method of claim 1, further comprising:
forming a backside router dielectric layer on a backside surface of the router substrate after thinning the router substrate; and
forming backside router bonding pads within the backside router dielectric layer on the end surfaces of the router through-substrate via structures.

10. The method of claim 9, wherein:
the memory dies comprise high-bandwidth memory (HBM) memory dies including a respective vertical stack of dynamic random access memory (DRAM) dies; and
bonding pads of the memory dies are bonded to the backside router bonding pads via metal-to-metal bonding.

11. A semiconductor assembly comprising:
a plurality of processor dies bonded to an interposer structure including interposer dielectric material layers having formed therein interposer metal interconnect structures;
a dielectric matrix laterally surrounding the plurality of processor dies;
a router die bonded to the plurality of processor dies and comprising router dielectric material layers having formed therein router metal interconnect structures and router substrate having formed therein router through-substrate via structures; and
memory dies comprising bonding pads that are electrically connected to the router through-substrate via structures.

12. The semiconductor assembly of claim 11, wherein the plurality of processor dies comprises:
processor-die substrates having formed therein die through-substrate via structures; and
backside processor bonding pads located on the die through-substrate via structures and bonded to front interposer bonding pads formed within the interposer dielectric material layers of the interposer structure.

13. The semiconductor assembly of claim 11, wherein:
the plurality of processor dies comprises backside die dielectric layers laterally surrounding the backside processor bonding pads; and
surfaces of the backside die dielectric layers are bonded to surface segments of the interposer dielectric material layers via dielectric-to-dielectric bonding.

14. The semiconductor assembly of claim 11, wherein sidewalls of the interposer structure are vertically coincident with sidewalls of the router die.

15. The semiconductor assembly of claim 11, wherein front router bonding pads which are formed within the router dielectric material layers are bonded to front processor bonding pads which are formed within the die dielectric material layers of the plurality of processor dies.

16. A semiconductor assembly comprising:
an interposer structure comprising interposer dielectric material layers having formed therein interposer metal interconnect structures and front interposer bonding pads;
a plurality of processor dies formed within a dielectric matrix and comprising first processor bonding pads that are bonded to the front interposer bonding pads;
a router die comprising router dielectric material layers having formed therein router metal interconnect structures and front router bonding pads and further comprising router substrate having formed therein router through-substrate via structures, wherein the front router bonding pads are bonded to second processor bonding pads within the plurality of processor dies; and
memory dies that are bonded to router die, wherein the memory dies comprise memory-die bonding pads that are electrically connected to the router through-substrate via structures.

17. The semiconductor assembly of claim 16, wherein the router die comprises a backside router dielectric layer located on a backside surface of the router substrate and having formed therein backside router bonding pads which are in contact with end surfaces of the router through-substrate via structures.

18. The semiconductor assembly of claim 17, wherein the memory dies comprise bonding pads which are bonded to the backside router bonding pads via metal-to-metal bonding.

19. The semiconductor assembly of claim 16, wherein sidewalls of the router die are vertically coincident with sidewalls of the dielectric matrix.

20. The semiconductor assembly of claim 16, wherein:
the plurality of processor dies comprises die dielectric material layers having formed therein die metal interconnect structures and front processor bonding pads;
the router dielectric material layers having formed therein front router bonding pads; and
the front router bonding pads are bonded to the front processor bonding pads via metal-to-metal bonding.
